(19) United States
(12) Patent Application Publication
(10) Pub. No.: US 2006/0257753 A1
(43) Pub. Date: Nov. 16, 2006

(54) Photomask and method thereof

(76) Inventors: Won-joo Kim, Suwon-si (KR); I-hun Song, Seongnam-si (KR); Suk-pil Kim, Yongin-si (KR); Seung-hyuk Chang, Seongnam-si (KR); Won-Il Ryu, Seoul (KR); Hoon Kim, Po-dong Siheung-si (KR)

Correspondence Address: HARNESS, DICKEY & PIERCE, P.L.C., P.O. BOX 8910, RESTON, VA, 20195, US

(21) Appl. No.: 11/356,258

(22) Filed: Feb. 17, 2006

(30) Foreign Application Priority Data
Feb. 18, 2005 (KR) 10-2005-0013527

(51) Int. Cl. G03C 5/00; G21K 5/00; G03F 1/00

(52) U.S. Cl. 430/5; 378/35; 430/322; 430/323; 430/324

(57) ABSTRACT

A photomask and method thereof. In an example method, a photomask may be manufactured by forming an oxide layer on a surface, patterning the oxide layer to form an oxide pattern, the oxide pattern including a plurality of oxide pattern bodies and a plurality of oxide windows, filling the plurality of oxide windows with an absorbent to form an absorbent pattern and reducing the plurality of oxide pattern bodies. An example photomask may include an oxide pattern-based absorbent pattern including a plurality of absorbent pattern bodies and a plurality of absorbent pattern windows.

### PRIORITY STATEMENT

This application claims the benefit of Korean Patent Application No. 10-2005-0013527, filed on Feb. 18, 2005, in the Korean Intellectual Property Office, the disclosure of which is incorporated herein in its entirety by reference.

### BACKGROUND OF THE INVENTION

1. Field of the Invention

Example embodiments of the present invention relate generally to a photomask and method thereof.

2. Description of the Related Art

As the integration density of semiconductor devices increases, wafer patterning may become a more significant design factor. Also, various light sources, such as an Extreme Ultra Violet Lithography (EUVL) light source, which may have a shorter wavelength as compared to a krypton fluoride (KrF) light source and/or an argon fluoride (ArF) light source, may be employed to increase a resolution by shortening the wavelength of projected light.

EUVL optical systems may include electromagnetic waves having a shorter wavelength (e.g., lower than the Krf and/or ArF light sources or 13.4 nm). EUVL optical systems may be configured differently as compared to the Krf and/or ArF systems. For example, in conventional optical systems including an ArF light source and/or a KrF light source, light or electromagnetic waves may be transmitted using a quartz photomask. By contrast, in EUVL optical systems, light or electromagnetic waves may be transmitted using a reflection (or mirror) photomask. In EUVL optical systems, light (e.g., including ultraviolet light) having shorter wavelengths may be readily absorbed by a transmission mask.

FIG. 1 is a schematic drawing of a conventional EUVL exposing apparatus 10. Referring to FIG. 1, a laser emitted from a laser source 5 of the EUVL exposing apparatus 10 may be received by an illuminating system 30 and may pass through an optical lens C1 after being reflected from a mirror in a laser drive optics 20. The laser may excite Xenon (Xe) gas supplied through a Xe gas supply tube 7. EUVL light may thereby be generated by plasma sources 9 formed by the laser. The generated EUVL light may be filtered at a spectral purity filter 11 which may be incident upon a photomask stage chamber 40 after reflecting from optical lenses C2 and C3.

Referring to FIG. 1, a movable reflection type photomask 13 for EUVL light may be mounted in the photomask stage chamber 40. EUVL light incident on the photomask 13 may have an optical profile forming a pattern after reflecting from the photomask 13. The EUVL light reflected by the photomask 13 may be received by a wafer stage chamber 60 after reflecting off of mirrors M1, M2, M3, and/or M4. A movable wafer 15 to be patterned may be mounted in the wafer stage chamber 60. A pattern may be formed on the wafer 15 by the EUVL light incident upon the wafer 15. Accordingly, a reflection type photomask may be employed by the EUVL exposing apparatus 10 instead of a transmission type photomask.

FIGS. 2A through 2G are cross-sectional views illustrating a conventional process of manufacturing a reflection photomask.

Referring to FIGS. 2A and 2B, a substrate 70 may be prepared, and a reflection layer 71 may be formed on the substrate 70. In an example, the reflection layer 71 may be formed by alternately stacking molybdenum film layers and silicon film layers.

Referring to FIG. 2C, an absorbent layer 72 may be formed on the reflection layer 71. The absorbent layer 72 may include a material capable of absorbing EUVL light. Referring to FIG. 2D, a resist layer 73 may be formed on the absorbent layer 72. The resist layer 73 may pattern the absorbent layer 72. Referring to FIG. 2E, a resist pattern 74 may be formed by patterning the resist layer 73. The resist pattern 74 may include resist pattern bodies 75 having intervening resist pattern body holes 76.

Referring to FIG. 2F, an absorbent pattern 77 may be formed by patterning the absorbent layer 72 using the resist pattern 74 as a mask. The absorbent layer 72 may be patterned by an etching process. The absorbent pattern 77 may include absorbent pattern bodies 78 arranged under the resist pattern bodies 75, and windows 79 formed between adjacent absorbent pattern bodies 78.

Referring to FIG. 2G, the resist pattern 74 may be removed, and a resultant product may a reflection photomask. In FIG. 2G, reference numeral 80 may indicate a line critical dimension (CD), reference numeral 81 may indicate a space CD, reference numeral 82 may indicate a printed line CD formed on the silicon wafer 84 corresponding to the line CD 80, and reference numeral 83 may indicate a printed space CD formed on the silicon wafer 84 corresponding to the space CD 81.

In the above-described conventional fabrication process, the printed line CD 82 may not match the line CD 80, and the printed space line CD 83 may not match the space line CD 81. The pattern formed on the silicon wafer 84 using the absorbent pattern 77 may thereby be different than a desired pattern. The difference between the desired pattern and the actual pattern may limit a precision in etching the absorbent layer 72.

FIGS. 3 and 4 illustrate portions of a scanning electron microscope (SEM) image of a reflection photomask manufactured by the conventional process of FIGS. 2A-2G.

Referring to FIG. 3, side surfaces of the absorbent pattern bodies 78 may be undercut and an angle formed by the reflection layer 71 and the side surfaces of the absorbent pattern bodies 78 may be different as compared to a designed or desired angle (e.g., a 90 degree angle or right angle). For example, in FIG. 3 the side surfaces of the absorbent pattern bodies 78 may be concave (e.g., not formed at right angles).

Referring to FIG. 4, due to the precision limit in etching the absorbent layer 72, the side surfaces of the absorbent pattern bodies 78 may not be uniform (e.g., flat), and a portion of the reflection layer 71 may be etched. The surface of the reflection layer 71 may thereby contact the window 79, which may also subsequently not be uniform.

### SUMMARY OF THE INVENTION

An example embodiment of the present invention is directed to a method of manufacturing a photomask, including forming an oxide layer on a surface, patterning the oxide layer to form an oxide pattern, the oxide pattern including a plurality of oxide pattern bodies and a plurality of oxide windows, filling the plurality of oxide windows with an absorbent to form an absorbent pattern and reducing the plurality of oxide pattern bodies.

Another example embodiment of the present invention is directed to a photomask, including an oxide pattern-based absorbent pattern including a plurality of absorbent pattern bodies and a plurality of absorbent pattern windows.

### BRIEF DESCRIPTION OF THE DRAWINGS

The accompanying drawings are included to provide a further understanding of example embodiments of the invention, and are incorporated in and constitute a part of this specification. The drawings illustrate example embodiments of the present invention and, together with the description, serve to explain principles of the present invention.

FIG. 1 is a schematic drawing of a conventional Extreme Ultra Violet Lithography (EUVL) exposing apparatus.

FIGS. 2A through 2G are cross-sectional views illustrating a conventional process of manufacturing a photomask.

FIGS. 3 and 4 illustrate portions of a scanning electron microscope (SEM) image of a reflection photomask manufactured by the conventional process of FIGS. 2A-2G.

FIGS. 5A through 5F are cross-sectional views illustrating a process of manufacturing a photomask according to an example embodiment of the present invention.

FIGS. 6A through 6G illustrate a process of forming absorbent pattern bodies according to another example embodiment of the present invention.

FIGS. 7A through 7C are cross-sectional views illustrating a process of forming a reflection layer according to another example embodiment of the present invention.

FIGS. 8A through 8E are cross-sectional views illustrating a process of manufacturing a reflection photomask having absorbent pattern bodies formed according to the process described of FIGS. 6A through 6G and a reflection layer formed according to the process of FIGS. 7A through 7C according to another example embodiment of the present invention.

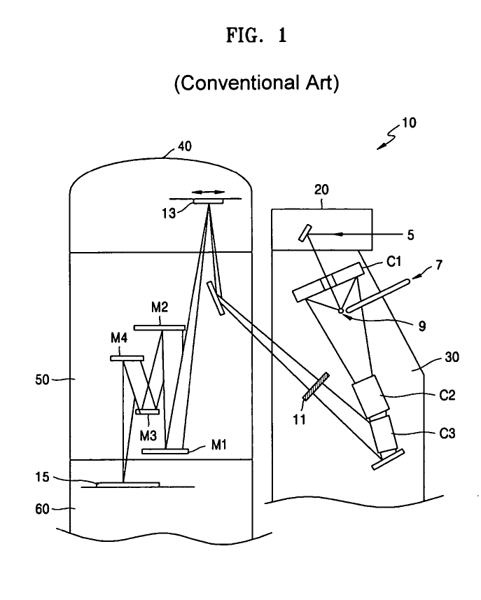

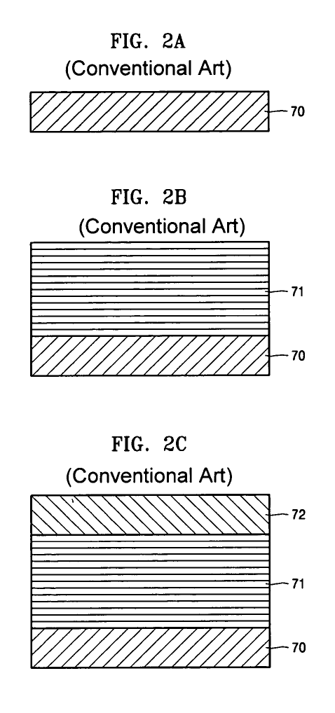

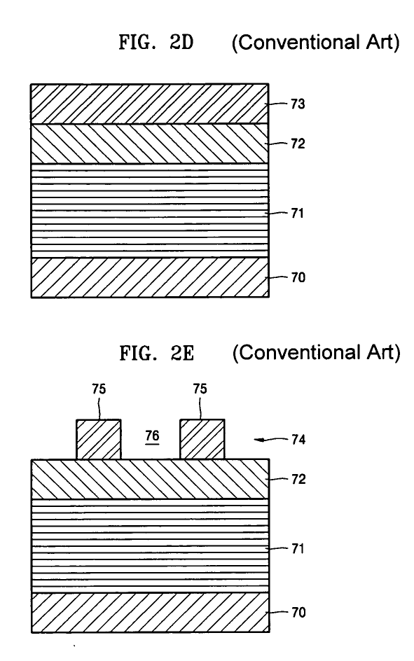

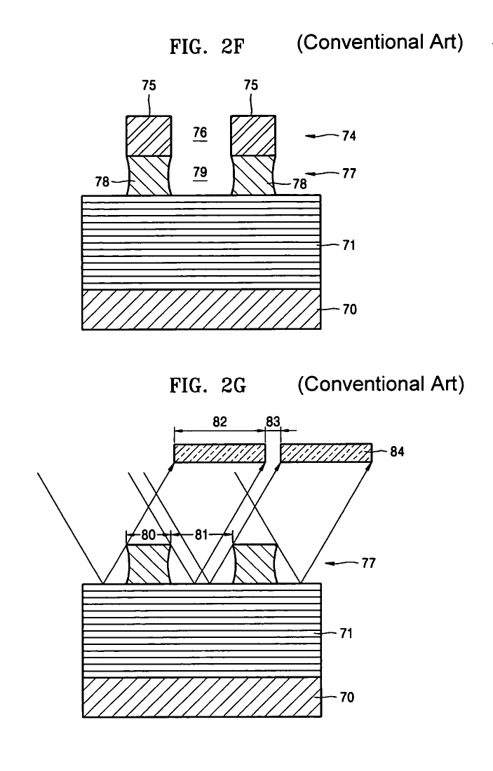

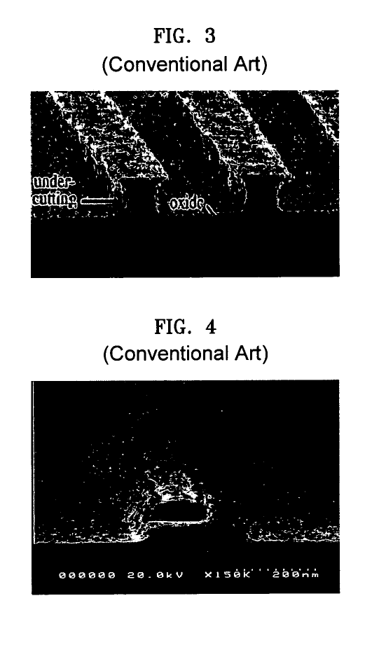

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

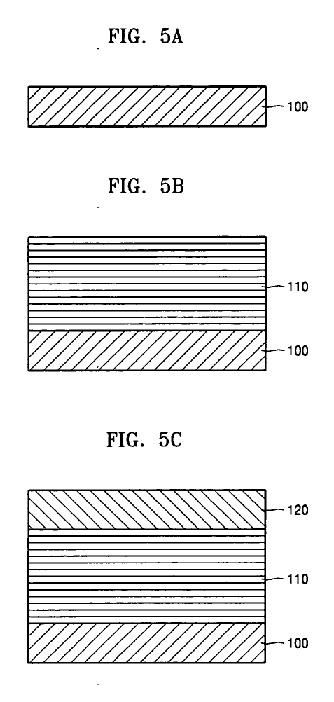

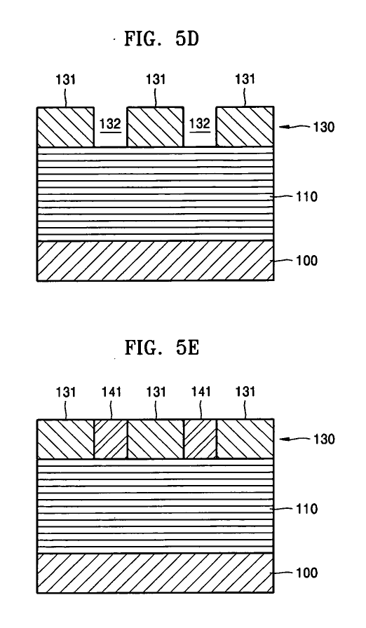

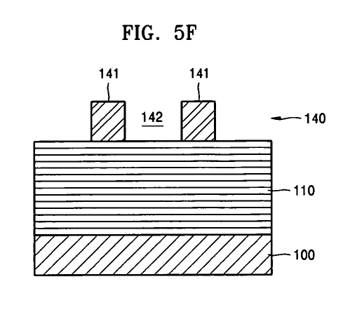

FIGS. 5A through 5F are cross-sectional views illustrating a process of manufacturing a photomask according to an example embodiment of the present invention.

In the example embodiment of FIG. 5A, a substrate 100 may be prepared. In an example, the substrate 100 may include silicon (Si). In the example embodiment of FIG. 5B, a reflection layer 110 may be formed on the substrate 100. In an example, the reflection layer 110 may be formed by alternately stacking a plurality of molybdenum Mo film layers and silicon Si film layers. In a further example, the uppermost film layer of the reflection layer 110 may be either a molybdenum Mo film layer or a silicon Si film layer. In an example, if the uppermost film layer is a silicon Si film layer, a stability of the uppermost surface may be increased. In another example, the thickness of each silicon Si film layer and molybdenum Mo film layer may be relatively small (e.g., a few nanometers (nm)). In another example, the molybdenum Mo and silicon Si film layers may collectively number between 10 and 100.

In the example embodiment of FIG. 5B, one or more of the molybdenum Mo film layers in the reflection layer 110 may alternatively be replaced by a film layer including one or more of Sc, Ti, V, Cr, Fe, Ni, Co, Zr, Nb, Tc, Ru, Rh, Hf, Ta, W, Re, Os, Ir, Pt, Cu, Pd, Ag, and/or Au. Likewise, one or more of the silicon Si film layers in the reflection layer 110 may alternatively be replaced by a film layer including one or more of tantalum nitride, silicon carbon, silicon nitride, silicon oxide, boron nitride, beryllium nitride, beryllium oxide, aluminium nitride, or aluminium oxide. It is understood that the above-described sets of replacement film layer materials represent non-exhaustive sets of potential replacements.

In the example embodiment of FIG. 5C, an oxide layer 120 may be formed on the reflection layer 110. The oxide layer may be conducive to etching, and thereby may be patterned to form an absorbent pattern. In an example, the oxide layer 120 may be formed with a chemical vapor deposition (CVD) process.

In the example embodiment of FIG. 5D, an oxide pattern 130 may be formed by patterning the oxide layer 120 (e.g., with an etching process). The oxide pattern 130 may include oxide pattern bodies 131 and oxide windows 132 (e.g., gaps or holes) formed between adjacent oxide pattern bodies 131. Side surfaces of the oxide pattern bodies 131 adjacent to the oxide windows 132 may not be undercut, and an angle between the side surfaces of the oxide pattern bodies 131 and the reflection layer 110 may thereby be configured to achieve a desired angle (e.g., a right angle). In an example, the side surfaces of the oxide pattern bodies 131 may be etched to make a right angle with respect to the reflection layer 110 such that the side surfaces of absorbent patterns (e.g., to be filled in the oxide windows 132) may make a right angle with the reflection layer 110. In an alternative example, the side surfaces of the oxide pattern bodies 131 may be etched to make an angle equal to the incidence angle of UV beams such that the side surfaces of absorbent patterns (e.g., to be filled in the oxide windows 132) may make an angle equal to the incidence angle of UV beams. In a further example, the side surfaces of the oxide pattern bodies 131 may be formed uniformly, and an etching of the surfaces of the reflection layer 110 adjacent to the oxide windows 132 may thereby be reduced. In general, it is understood that the oxide pattern bodies 131 and oxide windows 132 may be formed in accordance with a desired shape and/or angle associated with absorbent pattern bodies, which will now be described.

In the example embodiment of FIG. 5E, an absorbent that may absorb EUVL light may be formed in the oxide windows 132 of the oxide pattern 130 to form absorbent pattern bodies 141. In an example, the absorbent may include chromium Cr and/or tantalum nitride. An upper surface of the absorbent pattern bodies 141 may be polished to obtain a uniform surface (e.g., using chemical mechanical polishing (CMP) process).

In the example embodiment of FIG. 5F, the oxide pattern bodies 131 may be reduced (e.g., removed), and an absorbent pattern 140 (e.g., in positions previously corresponding to oxide windows 132) may remain including the absorbent pattern bodies 141 and an absorbent window 142 formed between the absorbent pattern bodies 141. In an example, the oxide pattern bodies 131 may be removed with a wet etching process. In another example, if fluoride is used for etching the oxide pattern bodies 131, the oxide pattern bodies 131 may be removed without damaging the absorbent pattern bodies 141 (e.g., because the absorbent pattern bodies 141 may be resistant to fluoride).

In the example fabrication process described above with respect to FIGS. 5A-5F, a precision of forming the absorbent pattern 140 may be increased by using the oxide pattern 130 which may be formed by patterning the oxide layer 120. Undercuts of the side surfaces of the absorbent pattern bodies 141 adjacent to the oxide windows 132 may thereby be reduced through the use of the oxide pattern 130 as a “mold”. Further, an angle between the side surfaces of the oxide pattern bodies 131 and the reflection layer 110 may formed more accurately (e.g., with respect to a target or desired angle formation), which may thereby result in more accurate absorbent pattern bodies 141. Further, an etching of the surface of the reflection layer 110 adjacent to the absorbent window 142 may be reduced. Further, the conventional patterning of a resist layer after forming the resist layer need not be performed in the above-described example embodiment, thereby simplifying a fabrication process of the photomask.

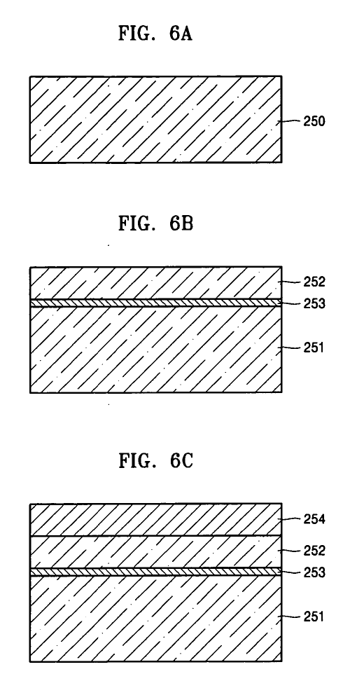

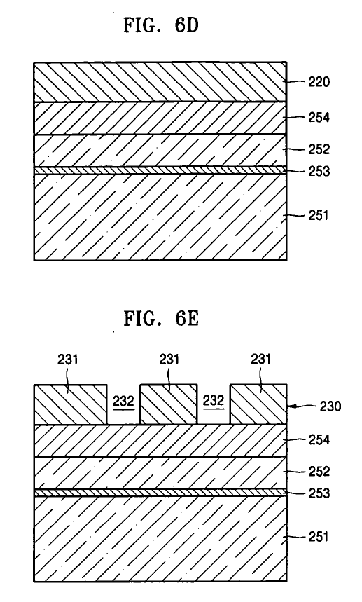

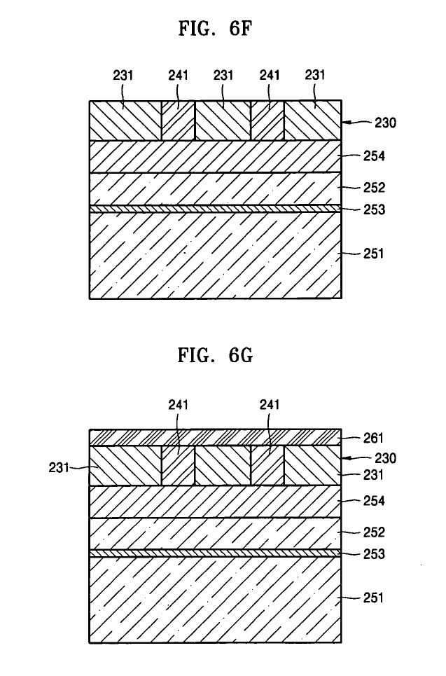

FIGS. 6A through 6G illustrate a process of forming absorbent pattern bodies according to another example embodiment of the present invention.

In the example embodiment of FIGS. 6A and 6B, a base 250 may be prepared. An ion layer 253 may be formed by implanting ions (e.g., hydrogen ions, boron ions, etc.) into the base 250. The base 250 may include a lower base 251 and an upper base 252 separated by the ion layer 253.

In the example embodiment of FIG. 6C, a nitride layer 254 may be formed on the upper base 252. The nitride layer 254 may function as an etch stopper when etching an oxide layer 220 (e.g., see FIG. 6D) which may be formed on the nitride layer 254. In the example embodiment of FIG. 6D, the oxide layer 220 may be formed on the nitride layer 254. The oxide layer 220 may be responsive to an etching process.

In the example embodiment of FIG. 6E, an oxide pattern 230 may be formed by patterning the oxide layer 220. The oxide pattern 230 may include oxide pattern bodies 231 separated by oxide windows 232. In the example embodiment of FIG. 6F, an absorbent (e.g., which may absorb EUVL light) may be formed in the oxide windows 232 of the oxide pattern 230 to form absorbent pattern bodies 241. In an example, the absorbent may include chromium Cr and/or tantalum nitride. The upper surface of the absorbent pattern bodies 241 may be polished to a form a uniform surface (e.g., using a chemical mechanical polishing (CMP)).

In the example embodiment of FIG. 6G, an adhesion layer 261 may be formed on the oxide pattern 230 and the absorbent pattern bodies 241. In an example, the adhesion layer 261 may include a hydrophilic material (e.g., which may attract water), such as a silicon oxide.

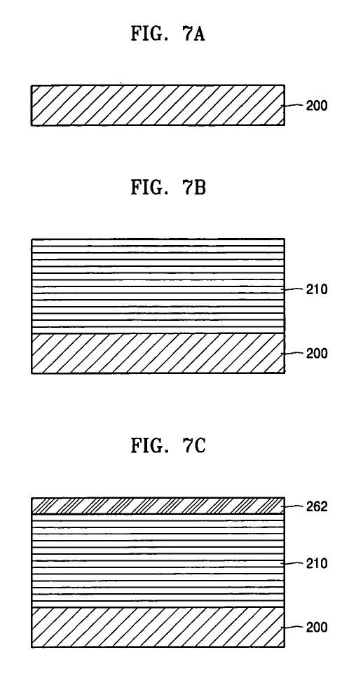

An example method of forming a reflection layer according to another example embodiment of the present invention will now be described with respect to FIGS. 7A through 7C.

FIGS. 7A through 7C are cross-sectional views illustrating a process of forming a reflection layer according to another example embodiment of the present invention.

In the example embodiment of FIGS. 7A and 7B, a substrate 200 may be prepared and a reflection layer 210 may be formed on the substrate 200. In an example, the reflection layer 210 may be formed by alternately stacking a plurality of molybdenum Mo film layers and silicon Si film layers. However, it is understood that other example embodiments of the present invention may replace one or more of the molybdenum Mo film layers in the reflection layer 210 with a film layer including one or more of Sc, Ti, V, Cr, Fe, Ni, Co, Zr, Nb, Tc, Ru, Rh, Hf, Ta, W, Re, Os, Ir, Pt, Cu, Pd, Ag, and/or Au. Likewise, one or more of the silicon Si film layers in the reflection layer 210 may alternatively be replaced by a film layer including one or more of tantalum nitride, silicon carbon, silicon nitride, silicon oxide, boron nitride, beryllium nitride, beryllium oxide, aluminium nitride, or aluminium oxide. It is understood that the above-described sets of replacement film layer materials represents a non-exhaustive set of potential replacements.

In the example embodiment of FIG. 7C, an adhesion layer 262 may be formed on the reflection layer 210. In an example, the adhesion layer 262 may include a hydrophilic material (e.g., which may attract water), such as a silicon oxide. The resultant structure of the example embodiment of FIG. 7C may be representative of a reflection layer.

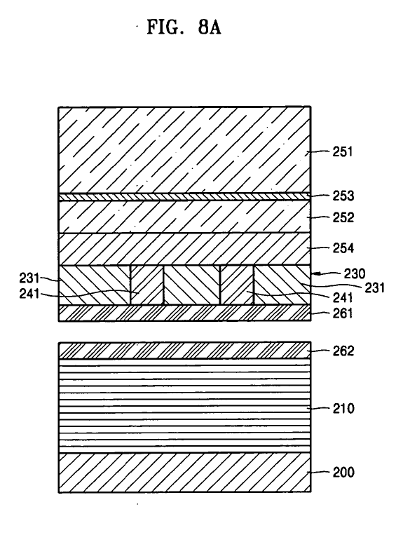

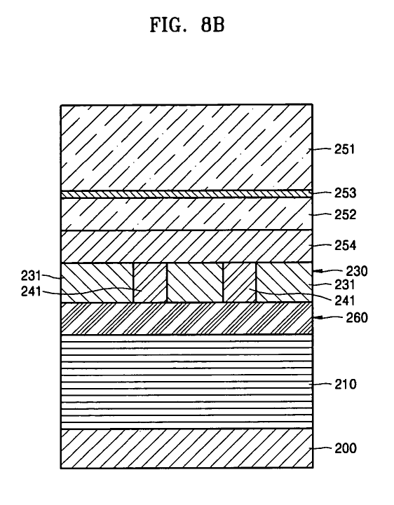

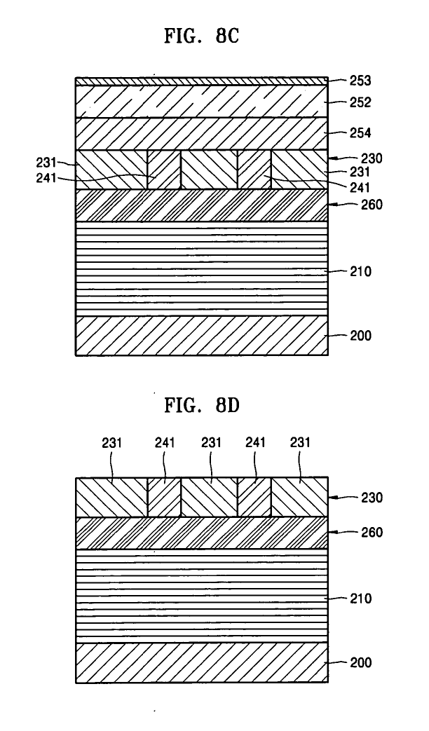

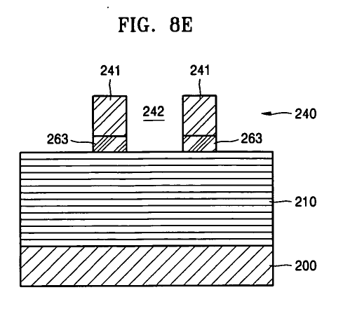

FIGS. 8A through 8E are cross-sectional views illustrating a process of manufacturing a reflection photomask having absorbent pattern bodies formed according to the process described of FIGS. 6A through 6G and a reflection layer formed according to the process of FIGS. 7A through 7C according to another example embodiment of the present invention.

In the example embodiment of FIG. 8A, the lower base 251 (e.g., inverted from the orientation illustrated in the example embodiments of FIGS. 6B-6G) including the absorbent pattern bodies 241, the oxide pattern 230, and a substrate 200 including the reflection layer 210, may be prepared.

In the example embodiment of FIG. 8B, an adhesion part 260 may be formed by bonding the adhesion layer 261 formed on the oxide pattern 230 and the adhesion layer 262 formed on the reflection layer 210 (e.g., using a silicon wafer bonding technique). In an example, the two adhesion layers 261 and 262 may each include silicon, for example silicon oxide. In a further example, the adhesion part 260 may have a Si—O—Si structure and/or other composition having a relatively strong adhesive or bonding force. The absorbent pattern bodies 241 formed on the oxide pattern 230 may thereby bond reliably to the reflection layer 210.

In the example embodiment of FIG. 8C, the lower base 251 on the ion layer 253 may be reduced (e.g., removed). In an example, if the ions within the ion layer 253 include hydrogen ions, the lower base 251 may be reduced (e.g., removed) by heating the ion layer 253. If the ion layer 253 is heated with a given energy (e.g., which may be expressed in Joules), the ion layer 253 and the lower base 251 may be separated by a vibration characteristic of hydrogen ions in the ion layer 253 (e.g., in response to the applied heat). In an alternative example, if the ions within the ion layer 253 include boron ions, the lower base 251 may be reduced (e.g., removed) by with an etching agent (e.g., Potassium Hydroxide (KOH), tetramethylammonium hydroxide (TMAH), etc.). The etching agent may etch the lower base 251 (e.g, including silicon) until the etching reaches the ion layer 253 having the boron ions, thereby reducing (e.g., removing) the lower base 251.

In the example embodiment of FIG. 8D, the ion layer 253 and the upper base 252 may be reduced (e.g., removed) by reducing (e.g., removing) the nitride layer 254 on the oxide pattern 230.

In the example embodiment of FIG. 8E, the oxide pattern bodies 231 may be reduced (e.g., removed) by a wet etching process. In an example, if fluoride is used for etching the oxide pattern bodies 231, the oxide pattern bodies 231 may be reduced (e.g., removed) without damaging the absorbent pattern bodies 241 (e.g., including chromium Cr). Adhesion part portions 263, in positions corresponding to (e.g., underneath) the absorbent pattern bodies 241, may be formed during the wet etching process as applied to the adhesion part 260. The example embodiment of FIG. 8E may illustrate a reflection photomask according to another example embodiment of the present invention.

In another example embodiment of the present invention, a higher precision absorbent pattern may be formed because the absorbent pattern may be formed by using an oxide layer as a mold. An undercutting of side surfaces of absorbent pattern bodies adjacent to the absorbent windows may thereby be reduced and an angle between the side surfaces of the absorbent pattern bodies and a reflection layer may achieve a given angle (e.g., a right angle). Further, an etching of the surface of the reflection layer adjacent to the absorbent window may be reduced. A resultant reflection photomask may be printed on a silicon wafer.

Example embodiments of the present invention being thus described, it will be obvious that the same may be varied in many ways. For example, while above-described example embodiments of the present invention are directed to reflection photomasks, it is understood that other example embodiments of the present invention may be directed to achieving higher precision pattern bodies (e.g., oxide pattern bodies, absorbent pattern bodies, etc.) in any device.

Further, while above-described example embodiments are directed generally to EUVL light absorption/detection, other example embodiments may be directed to other types of light and/or non-light applications.

Such variations are not to be regarded as a departure from the spirit and scope of example embodiments of the present invention, and all such modifications as would be obvious to one skilled in the art are intended to be included within the scope of the following claims.

What is claimed is:

1. A method of manufacturing a photomask, comprising:
forming an oxide layer on a surface;
patterning the oxide layer to form an oxide pattern, the oxide pattern including a plurality of oxide pattern bodies and a plurality of oxide windows;
filling the plurality of oxide windows with an absorbent to form an absorbent pattern; and
reducing the plurality of oxide pattern bodies.

2. The method of claim 1, wherein the surface is a portion of a reflection layer.

3. The method of claim 2, wherein the reflection layer is capable of reflecting extreme ultra violet lithography (EUVL) light.

4. The method of claim 2, further comprising:
forming the reflection layer on a substrate.

5. The method of claim 1, wherein at least one of the plurality of oxide windows is formed between adjacent oxide pattern bodies.

6. The method of claim 1, wherein reducing the plurality of oxide pattern bodies fully removes the plurality of oxide pattern bodies.

7. The method of claim 1, wherein the absorbent is capable of absorbing extreme ultra violet lithography (EUVL) light.

8. The method of claim 1, further comprising:
polishing the absorbent pattern.

9. The method of claim 8, wherein the polishing is performed using a chemical mechanical polishing (CMP) process.

10. The method of claim 1, wherein forming the oxide layer is performed using a chemical vapor deposition (CVD) process.

11. The method of claim 1, wherein the absorbent includes at least one of chromium Cr and tantalum nitride TaN.

12. The method of claim 1, wherein reducing the plurality of oxide pattern bodies is performed with a wet etching process.

13. The method of claim 12, wherein the wet etching process includes fluoride.

14. The method of claim 2, wherein angles between side surfaces of the plurality of oxide pattern bodies and the reflection layer are set to at least one of a first angle approximating a right angle and a second angle approximating an incidence angle of ultraviolet beams.

15. The method of claim 1, further comprising:
forming a base and a reflection layer, wherein the oxide layer is formed on the surface of the base.

16. The method of claim 15, further comprising:
bonding the oxide pattern and the reflection layer.

17. The method of claim 15, further comprising:
reducing the base.

18. The method of claim 17, wherein reducing the base fully removes the base.

19. The method of claim 15, wherein forming the base includes forming an ion layer within the base by implanting ions into the base.

20. The method of claim 19, wherein the ions include at least one of hydrogen ions and boron ions.

21. The method of claim 19, wherein reducing the base includes separating a first base portion on a first side of the ion layer from a second base portion on a second side of the ion layer.

22. The method of claim 19, wherein reducing the base includes applying heat to the ion layer.

23. The method of claim 17, wherein the base is reduced with an etching agent.

24. The method of claim 23, wherein the etching agent includes at least one of potassium hydroxide (KOH) and tetramethylammonium hydroxide (TMAH).

25. The method of claim 15, wherein forming the base includes forming a nitride layer on the base.

26. The method of claim 25, wherein the oxide layer is formed on the nitride layer.

27. The method of claim 26, wherein reducing the base includes separating the nitride layer and the oxide pattern.

28. The method of claim 16, wherein bonding the oxide pattern and the reflection layer includes applying an adhesion layer between the oxide pattern and the reflection layer.

29. The method of claim 28, wherein the adhesion layer includes silicon oxide.

30. The method of claim 28, wherein the adhesion layer includes a first adhesion portion applied to the oxide pattern and a second adhesion portion applied to the reflection layer.

31. The method of claim 30, wherein at least one of the first and second adhesion portions includes silicon oxide.

32. A photomask, comprising:
an oxide pattern-based absorbent pattern including a plurality of absorbent pattern bodies and a plurality of absorbent pattern windows.

33. The photomask of claim 32, further comprising:
a reflection layer for reflecting light, an angle between side surfaces of each of the plurality of absorbent pattern bodies and the reflection layer being formed at a given angle.

34. The photomask of claim 32, wherein an oxide pattern used to form the oxide pattern-based absorbent pattern includes a plurality of oxide pattern bodies and a plurality of oxide windows, the plurality of oxide windows being used as a mold within which the plurality of absorbent pattern bodies are formed.

35. A method of forming the photomask of claim 32.
